(19) United States
(12) Patent Application Publication
(10) Pub. No.: US 2025/0107395 A1
(43) Pub. Date: Mar. 27, 2025

(54) DISPLAY DEVICE

(71) Applicant: Samsung Display Co., LTD., Yongin-si (KR)

(72) Inventors: Ju Yeop SEONG, Yongin-si (KR); In Woo JEONG, Yongin-si (KR); Jin Young YU, Yongin-si (KR)

(21) Appl. No.: 18/678,389

(22) Filed: May 30, 2024

(30) Foreign Application Priority Data
Sep. 25, 2023 (KR) 10-2023-0127871

(51) Int. Cl. H10K 59/80; H10K 59/131; H10K 59/40; H10K 77/10; H10K 102/00

(52) U.S. Cl. CPC H10K 59/87; H10K 59/131; H10K 59/40; H10K 77/111; H10K 2102/311

(57) ABSTRACT

A display device includes: a display panel including a main area and a sub-area, where the sub-area is bent and extended from the main area; a reinforcing member disposed between the main area and the sub-area of the display panel and connected to the display panel; and a circuit component disposed on the reinforcing member.

This application claims priority to Korean Patent Application No. 10-2023-0127871, filed on Sep. 25, 2023, and all the benefits accruing therefrom under 35 U.S.C. 119, the content of which in its entirety are herein incorporated by reference.

### BACKGROUND

### Technical Field

The present disclosure relates to a display device, and more particularly, to a display device that may reduce a manufacturing cost.

### Description of the Related Art

An organic light emitting display apparatus includes a display element, of which luminance is changed by a current, for example, an organic light emitting diode.

### SUMMARY

An aspect of the present disclosure is to provide a display device that may reduce a manufacturing cost.

The aspects of the present disclosure are not limited to those mentioned above and additional aspects of the present disclosure, which are not mentioned herein, will be clearly understood by those skilled in the art from the following description of the present disclosure.

According to an embodiment of the disclosure, a display device includes: a display panel including a main area and a sub-area, where the sub-area is bent and extended from the main area; a reinforcing member disposed between the main area and the sub-area of the display panel and connected to the display panel; and a first circuit component disposed on the reinforcing member.

In an embodiment, the reinforcing member may be directly connected to the sub-area of the display panel.

In an embodiment, the reinforcing member may be directly connected to an inner side of the sub-area of the display panel.

In an embodiment, the sub-area of the display panel may include: a bending area extended from the main area and bent; and a packaging area extended from the bending area and on which a second circuit component is disposed.

In an embodiment, the reinforcing member may be directly connected to the packaging area of the display panel.

In an embodiment, the reinforcing member may be directly connected to an inner side of the packaging area of the display panel.

In an embodiment, the display device may further include a conductive adhesive member physically and electrically connecting the reinforcing member to the packaging area of the display panel.

In an embodiment, the display device may further include a second circuit component disposed in the sub-area of the display panel.

In an embodiment, the display device may further include an intermediate board connecting the reinforcing member with the display panel.

In an embodiment, a first side of the intermediate board may be connected to the sub-area of the display panel, and a second side of the intermediate board may be connected to the reinforcing member.

In an embodiment, the sub-area of the display panel may include a bending area extended from the main area and bent; and a packaging area extended from the bending area and connected to the intermediate board, and on which a second circuit component is disposed.

In an embodiment, the first side of the intermediate board may be connected to the packaging area of the display panel.

In an embodiment, the first side of the intermediate board may be connected to an outer side of the packaging area of the display panel.

In an embodiment, the display device may further include: a first conductive adhesive member physically and electrically connecting the first side of the intermediate board with the packaging area of the display panel; and a second conductive adhesive member physically and electrically connecting the second side of the intermediate board with the reinforcing member.

In an embodiment, one end of the reinforcing member may face a bending area of the display panel.

In an embodiment, the reinforcing member may include one of a flexible printed circuit board, a printed circuit board, a chip on film and a rigid printed circuit board.

In an embodiment, the first circuit component on the reinforcing member may include a touch driver and a power supply unit.

In an embodiment, further including a display driver disposed on the display panel.

In an embodiment, the display driver may be disposed in the sub-area of the display panel.

In an embodiment, the reinforcing member may overlap the display driver in a plan view.

In the display device according to the present disclosure, a manufacturing cost may be effectively reduced.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view illustrating a display device according to an embodiment;

FIG. 2 is a cross-sectional view taken along line I-I′ of FIG. 1;

FIG. 3 is a view illustrating a display panel of FIG. 2;

FIG. 4 is a plan view illustrating a display device according to another embodiment;

FIG. 5 is a plan view illustrating a display device in which a circuit board is removed from FIG. 4;

FIG. 6 is a cross-sectional view taken along line II-II′ of FIG. 4;

FIG. 7 is a plan view illustrating a display device according to still another embodiment;

FIG. 8 is a cross-sectional view taken along line III-III′ of FIG. 7;

FIG. 9 is a plan view illustrating a display device according to yet another embodiment;

FIG. 10 is a cross-sectional view taken along line IV-IV′ of FIG. 9;

FIG. 11 is a plan view illustrating a display device according to another embodiment;

FIG. 12 is a cross-sectional view taken along line V-V′ of FIG. 10;

FIG. 13 is a plan view illustrating a display device according to still another embodiment;

FIG. 14 is a cross-sectional view taken along line VI-VI′ of FIG. 13;

FIG. 15 is a plan view illustrating a display device according to yet another embodiment; and

FIG. 16 is a cross-sectional view taken along line VII-VII′ of FIG. 15.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, detailed embodiments will be described with reference to the accompanying drawings.

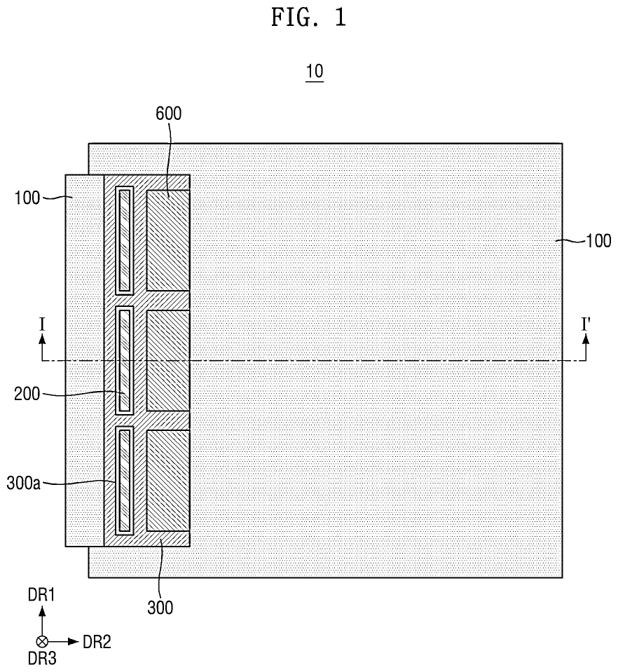

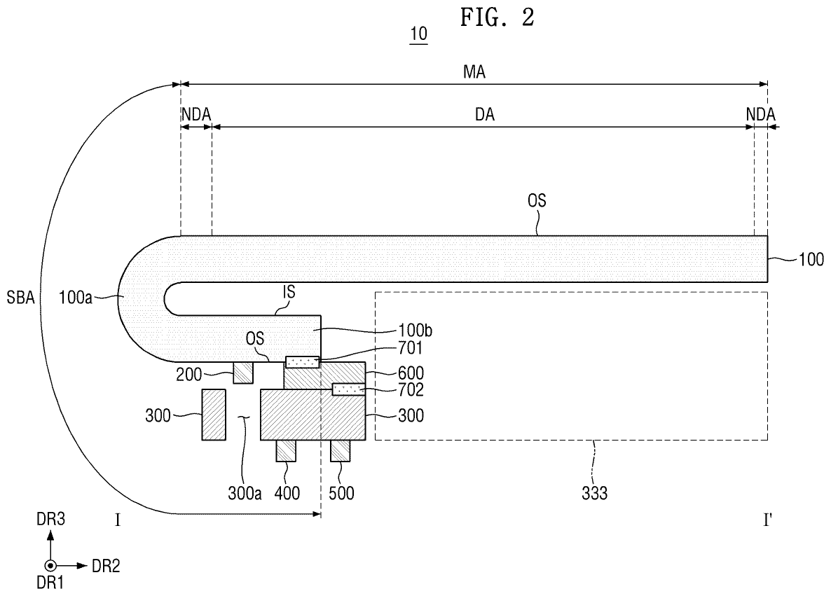

FIG. 1 is a plan view illustrating a display device according to one embodiment, and FIG. 2 is a cross-sectional view taken along line I-I′ of FIG. 1. FIG. 1 is a rear plan view in which a rear surface of the main area of the display panel 100 is shown. As used herein, the “plan view” is a view in a thickness direction (e.g., a third direction DR3) of the display device 10.

Referring to FIGS. 1 and 2, a display device 10 may be applied to a portable electronic device such as a mobile phone, a smart phone, a tablet personal computer (“PC”), a mobile communication terminal, an electronic diary, an electronic book, a portable multimedia player (“PMP”), a navigator and an ultra-mobile PC (“UMPC”). For example, the display device 10 may be applied to a television, a laptop computer, a monitor, a signboard or a display unit of Internet of things (“IoT”). For another example, the display device 10 may be applied to a wearable device such as a smart watch, a watch phone, an eyeglasses-type display and a head mounted display (“HMD”).

The display device 10 may have a planar shape similar to a rectangular shape. For example, the display device 10 may have a planar shape similar to a rectangular shape having short sides in a first direction DR1 and long sides in a second direction DR2. A corner where the short side of the first direction DR1 and the long side of the second direction DR2 meets may be rounded to have a predetermined curvature or formed at right angles. The planar shape of the display device 10 may be formed to be similar to other polygonal shape, a circular shape or an oval shape without being limited to the rectangular shape.

The display device 10 may include a display panel 100, a circuit component (e.g., a display driver 200, a touch driver 400, or a power supply unit 500), a circuit board 300, and an intermediate board 600.

The display panel 100 may include a main area MA and a sub-area SBA.

The main area MA of the display panel 100 may include a display area DA including pixels for displaying an image and a non-display area NDA disposed near the display area DA. The display area DA may emit light from a plurality of light emission areas or a plurality of opening areas. For example, the display panel 100 may include a pixel circuit including switching elements, a pixel defining layer defining light emission areas or opening areas, and a self-light emitting element.

For example, the self-light emitting element may include at least one of an organic light emitting diode including an organic light emitting layer, a quantum dot light emitting diode (“LED”) including a quantum dot light emitting layer, an inorganic LED including an inorganic semiconductor, or a micro LED.

The non-display area NDA may surround the display area DA. The non-display area NDA may be defined as an edge area of the main area MA of the display panel 100. The non-display area NDA may include a gate driver (not shown) for supplying gate signals to gate lines and fan-out lines (not shown) connecting the display driver 200 with the display area DA.

The sub-area SBA may be extended from one side of the main area MA. The sub-area SBA may include a flexible material capable of being subjected to bending, folding, rolling and/or the like. For example, when the sub-area SBA is bent, the sub-area SBA may overlap the main area MA in a thickness direction (e.g., a third direction DR3). The sub-area SBA may include a pad portion connected to the circuit board 300 and the display driver 200.

The sub-area SBA may include a bending area 100a and a packaging area 100b.

The bending area 100a may be disposed between the main area MA and the packaging area 100b. One side of the bending area 100a may be in contact with the main area MA, and the other side of the bending area 100a may be in contact with the packaging area 100b. The bending area 100a may have a U-shape (or U-shaped cross-section) convexly protruded in a reverse direction of the second direction DR2 in a bent state. The main area MA and the packaging area 100b may be connected to each other by the bending area 100a.

One side of the packaging area 100b may be in contact with the bending area 100a. When the display panel 100 is bent, the packaging area 100b may be disposed below the main area MA. For example, the packaging area 100b may be disposed below the main area MA to overlap the main area MA in the third direction DR3. In one embodiment, the packaging area 100b may overlap the non-display area NDA between the bending area 100a and a portion of the display area DA in the third direction DR3.

As described above, the display panel 100 has a bending shape in the bending area 100a, and the bent display panel 100 may have a U-shape (or U-shaped cross-section). A surface on which a screen is displayed on the bent display panel 100 is defined as an outer side OS of the display panel 100, and a surface opposite to the outer surface of the display panel 100 is defined as an inner side IS of the display panel 100.

The display driver 200 may output signals and voltages for driving the display panel 100. The display driver 200 may supply data voltages to data lines to the display panel 100. The display driver 200 may supply a power voltage to a power line and supply gate control signals to the gate driver. The display driver 200 may be formed of or include an integrated circuit (“IC”), and may be packaged on the display panel 100 by a chip on glass (“COG”) method, a chip on plastic (“COP”) method or an ultrasonic bonding method. For example, the display driver 200 may be disposed in the sub-area SBA, and may overlap the main area MA in the thickness direction (the third direction DR3) in a bend state of the sub-area SBA. For another example, the display driver 200 may be packaged on the circuit board 300.

The intermediate board 600 may be disposed between the display panel 100 and the circuit board 300. For example, the intermediate board 600 may be disposed between the packaging area 100b of the display panel 100 and the circuit board 300. The intermediate board 600 may electrically connect the display panel 100 with the circuit board 300. For example, one side (e.g., an upper surface) of the intermediate board 600 may be physically and electrically connected to the packaging area 100b of the display panel 100, and the other side (e.g., a bottom surface) of the intermediate board 600 may be physically and electrically connected to the circuit board 300.

The intermediate board 600 may be connected to the display panel 100 through a first conductive adhesive member 701. For example, a first pad portion (or a first bump) of the intermediate board 600 may be physically and electrically connected to a second pad portion disposed in the packaging area 100b of the display panel 100 (e.g., the outer side OS of the packaging area 100b) through the first conductive adhesive member 701. The first conductive adhesive member 701 may be, for example, an anisotropic conductive film (“ACF”).

In one embodiment, the intermediate board 600 may be, for example, a flexible printed circuit board (“FPCB”), a printed circuit board (“PCB”), or a flexible film such as a chip on film (“COF”).

The circuit board 300 may be connected to the intermediate board 600 through a second conductive adhesive member 702. For example, the pad portion (or bump) of the circuit board 300 may be physically and electrically connected to the second pad portion (or the second bump) of the intermediate board 600 through the second conductive adhesive member 702. The second conductive adhesive member 702 may be, for example, an anisotropic conductive film.

In one embodiment, the circuit board 300 may be, for example, a flexible printed circuit board (FPCB), a printed circuit board (PCB), or a flexible film such as a chip on film (COF).

In addition, the circuit board 300 may define a through hole 300a passing through the circuit board 300 in the third direction DR3. The through hole 300a of the circuit board 300 may be defined to correspond to the display driver 200, for example. In other words, the through hole 300a of the circuit board 300 may be disposed to overlap the display driver 200 in the third direction DR3. In a plan view as shown in FIG. 1, the through hole 300a may surround the display driver 200. When a thickness of the intermediate board 600 is small, the circuit board 300 and the display driver 200 may be in contact with each other when there is no through hole 300a. However, in an embodiment, the through hole 300a of the circuit board 300 may prevent the circuit board 300 and the display driver 200 from coming in contact with each other.

At least a portion of the circuit board 300 may overlap the sub-area SBA of the display panel 100 in the third direction DR3. For example, in a state that the display panel 100 is bent, at least a portion of the circuit board 300 may overlap the packaging area 100b of the sub-area SBA in the third direction DR3. In one embodiment, the circuit board 300 may overlap the display driver 200 in the third direction DR3. In one embodiment, a portion (hereinafter, an overlap portion) of the circuit board 300, which overlaps the sub-area SBA of the display panel 100, may have a larger area than a portion (hereinafter, a non-overlap portion) that does not overlap the sub-area SBA of the display panel 100. In other words, the area of the overlap portion may be larger than the area of the non-overlap portion. As the circuit board 300 is disposed to be closer to the sub-area SBA as described above, an area of a set area 333 may be increased. For example, components such as a frame, a battery and a camera may be disposed in the set area 333.

Circuit components such as a touch driver 400 and a power supply unit 500 may be disposed on the circuit board 300. For example, the touch driver 400 and the power supply unit 500 may be packaged on the circuit board 300.

The touch driver 400 may be electrically connected to a touch sensing unit of the display panel 100. The touch driver 400 may supply a touch driving signal to a plurality of touch electrodes of the touch sensing unit and sense a change amount of capacitance between the plurality of touch electrodes. For example, the touch driving signal may be a pulse signal having a predetermined frequency. The touch driver 400 may calculate whether input is performed and input coordinates based on the change amount of capacitance between the plurality of touch electrodes. The touch driver 400 may be formed of or include an integrated circuit (IC).

The power supply unit 500 may supply a power voltage to the display driver 200 and the display panel 100. The power supply unit 500 may generate a driving voltage to supply the driving voltage to a driving voltage line, generate an initialization voltage to supply the initialization voltage to an initialization voltage line and generate a common voltage to supply the common voltage to a common electrode common to light emitting elements of the plurality of pixels. For example, the driving voltage may be a high potential voltage for driving the light emitting element, and the common voltage may be a low potential voltage for driving the light emitting element.

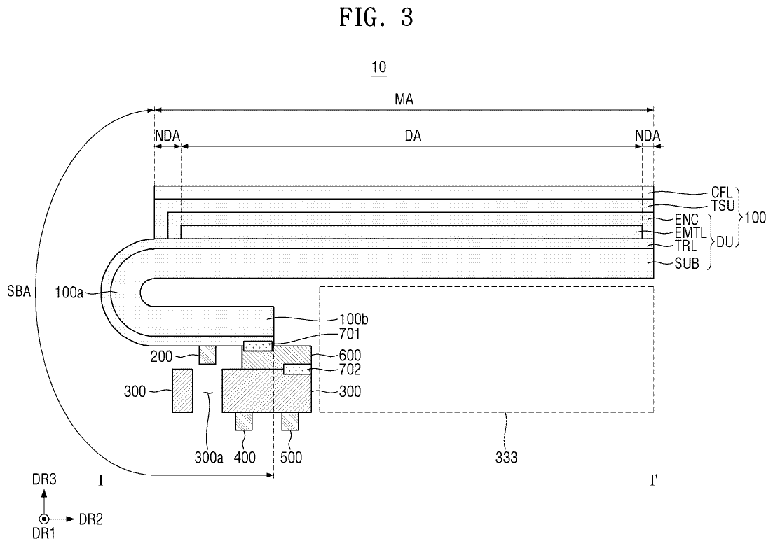

FIG. 3 is a view illustrating the display panel 100 of FIG. 2.

Referring to FIG. 3, the display panel 100 may include a display unit DU, a touch sensing unit TSU, and a color filter layer CFL. The display unit DU may include a substrate SUB, a transistor layer TRL, a light emitting element layer EMTL, and an encapsulation layer ENC.

The substrate SUB may be a base substrate or a base member. The substrate SUB may be a flexible substrate capable of being subjected to bending, folding, rolling or the like. For example, the substrate SUB may include a polymer resin such as polyimide (“PI)”, but is not limited thereto. For another example, the substrate SUB may include a glass material or a metal material.

The transistor layer TRL may be disposed on the substrate SUB. The transistor layer TRL may include a plurality of thin film transistors constituting a pixel circuit of pixels. The transistor layer TRL may further include gate lines, data lines, power lines, gate control lines, fan-out lines for connecting the display driver 200 with the data lines, and lead lines for connecting the display driver 200 with the pad portion. Each of the thin film transistors may include a semiconductor area, a source electrode, a drain electrode and a gate electrode. For example, when the gate driver is formed at one side of the non-display area NDA of the display panel 100, the gate driver may include thin film transistors.

The transistor layer TRL may be disposed in the display area DA, the non-display area NDA and the sub-area SBA. The thin film transistors, the gate lines, the data lines and the power lines of respective pixels of the transistor layer TRL may be disposed in the display area DA. The gate control lines and fan-out lines of the transistor layer TRL may be disposed in the non-display area NDA. The lead lines of the transistor layer TRL may be disposed in the sub-area SBA. The display driver 200, the first conductive adhesive member 701 and the intermediate board 600 may be disposed on the transistor layer.

The light emitting element layer EMTL may be disposed on the transistor layer TRL. The light emitting element layer EMTL may include a plurality of light emitting elements in which a pixel electrode, a light emitting layer and a common electrode are sequentially stacked to emit light, and a pixel defining layer for defining pixels. The plurality of light emitting elements of the light emitting element layer EMTL may be disposed in the display area DA.

For example, the light emitting layer may be an organic light emitting layer that includes an organic material. The light emitting layer may include a hole transporting layer, an organic light emitting layer and an electron transporting layer. When the pixel electrode receives a predetermined voltage through the thin film transistor of the thin film transistor layer TRL and the common electrode receives a cathode voltage, holes and electrons may move to the organic light emitting layer through the hole transporting layer and the electron transporting layer, respectively, and may be combined with each other in the organic light emitting layer to emit light. For example, the pixel electrode may be an anode electrode and the common electrode may be a cathode electrode, but the electrodes are not limited thereto.

For another example, the plurality of light emitting elements may include a quantum dot light emitting diode including a quantum dot light emitting layer, an inorganic light emitting diode including an inorganic semiconductor, or a micro light emitting diode.

The encapsulation layer ENC may cover an upper surface and sides of the light emitting element layer EMTL and protect the light emitting element layer EMTL. The encapsulation layer ENC may include at least one inorganic layer and at least one organic layer to encapsulate the light emitting element layer EMTL.

The touch sensing unit TSU may be disposed on the encapsulation layer TFEL. The touch sensing unit TSU may include a plurality of touch electrodes for sensing a user's touch in a capacitance manner and touch lines for connecting the plurality of touch electrodes with the touch driver 400. For example, the touch sensing unit TSU may sense a user's touch in a mutual capacitance manner or a self-capacitance manner.

For another example, the touch sensing unit TSU may be disposed on a separate substrate disposed on the display unit DU. In this case, the substrate for supporting the touch sensing unit TSU may be a base member for encapsulating the display unit DU.

The plurality of touch electrodes of the touch sensing unit TSU may be disposed in a touch sensor area overlapped with the display area DA. The touch lines of the touch sensing unit TSU may be disposed in a touch peripheral area overlapped with the non-display area NDA.

The color filter layer CFL may be disposed on the touch sensing unit TSU. The color filter layer CFL may include a plurality of color filters corresponding to the plurality of light emission areas, respectively. Each of the color filters may selectively transmit light of a particular wavelength and block or absorb light of another wavelength. The color filter layer CFL may absorb a portion of light introduced from the outside of the display device 10 to reduce reflective light due to external light. Therefore, the color filter layer CFL may prevent distortion of a color, which is caused by external light reflection, from occurring.

Since the color filter layer CFL is directly disposed on the touch sensing unit TSU, the display device 10 may not require a separate substrate for the color filter layer CFL. Therefore, a thickness of the display device 10 may be relatively reduced.

The sub-area SBA of the display panel 100 may be extended from one side of the main area MA. The sub-area SBA may include a flexible material capable of being subjected to bending, folding, rolling and/or the like. For example, when the sub-area SBA is bent, the sub-area SBA may overlap the main area MA in the thickness direction (e.g., the third direction DR3). The sub-area SBA may include a pad portion electrically connected to the circuit board 300 and the display driver 200.

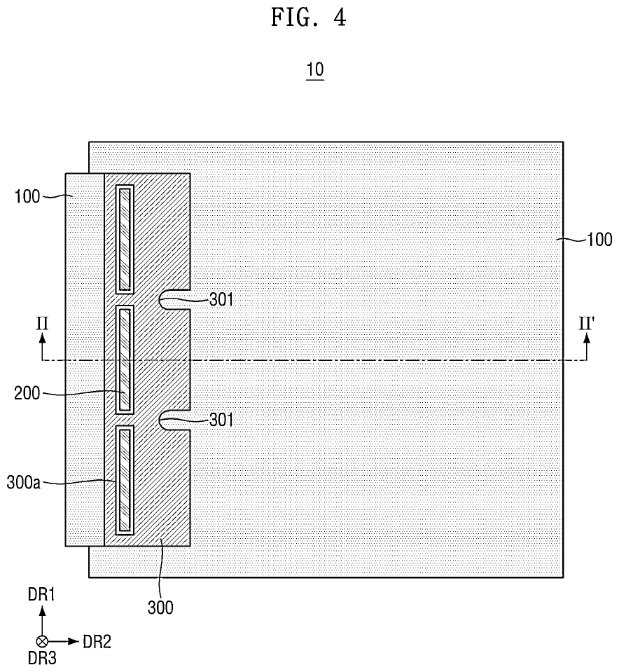

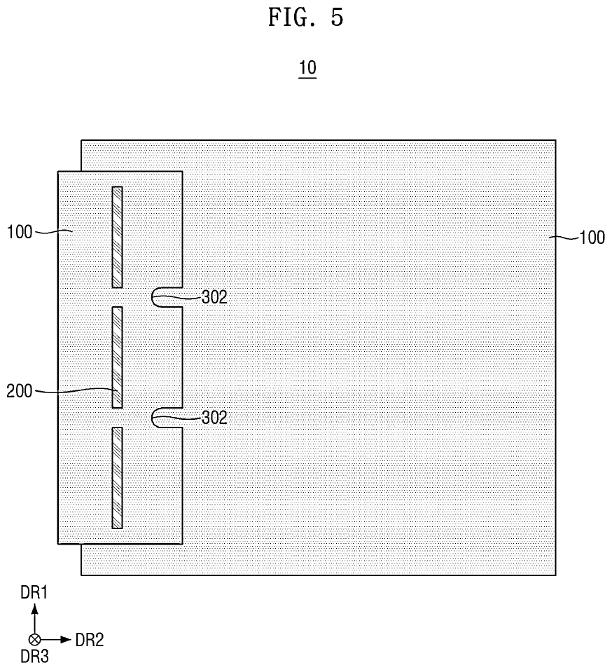

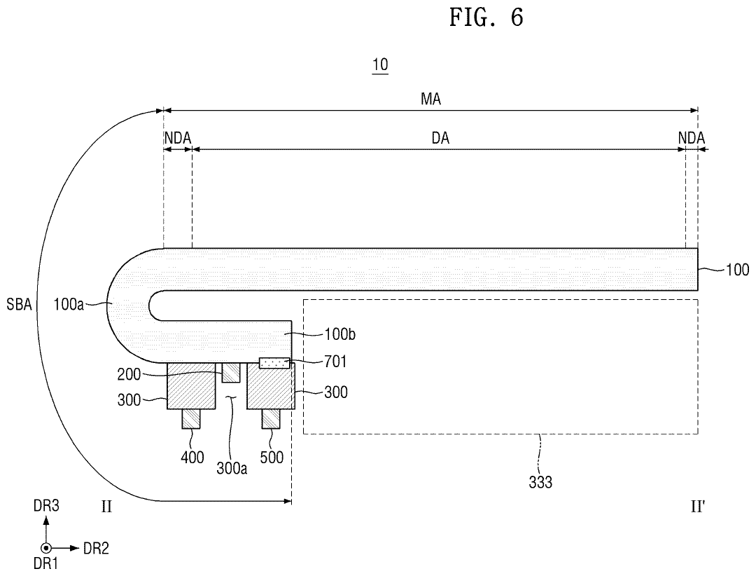

FIG. 4 is a plan view illustrating a display device according to another embodiment, FIG. 5 is a plan view illustrating a display device in which a circuit board is removed from FIG. 4, and FIG. 6 is a cross-sectional view taken along line II-II′ of FIG. 4.

Since the display device 10 of FIGS. 4 to 6 has a difference from the display device 10 of FIGS. 1 to 3 in the position of the circuit board 300, the following description will be based on the difference.

As shown in FIGS. 4 to 6, the circuit board 300 may be disposed on the packaging area 100b of the display panel 100. In one embodiment, the circuit board 300 may be in contact with the display panel 100 in the packaging area 100b. In other words, the circuit board 300 and the packaging area 100b of the display panel 100 may be directly in contact with each other. The circuit board 300 may be physically and electrically connected to the packaging area 100b of the display panel 100 (e.g., the outer side OS of the packaging area 100b) through the first conductive adhesive member 701. For example, the circuit board 300 may be directly connected to the display panel 100 without the aforementioned intermediate board 600.

As shown in FIGS. 4 and 6, the display driver 200 may be disposed in the through hole 300a of the circuit board 300.

In one embodiment, as shown in FIG. 4, the circuit board 300 may define at least one first groove 301 therein. The first groove 301 may have, for example, a concave shape recessed in a reverse direction (hereinafter, referred to as a second reverse direction) of the second direction DR2. The first groove 301 may improve rigidity of the circuit board 300.

In one embodiment, as shown in FIG. 5, the display panel 100 may define at least one second groove 302 therein. The second groove 302 may have, for example, a concave shape recessed in the second reverse direction. The second groove 302 may improve rigidity of the display panel 100. The second groove 302 may be defined to correspond to the first groove 301 described above. For example, as shown in FIG. 4, two first grooves 301 and two second grooves 302 may overlap each other in the third direction DR3. The first groove 301 and the second groove 302 may have the same size and shape.

According to the display device 10 of one embodiment shown in FIGS. 4 to 6, when the circuit board 300 and the display panel 100 are attached to each other, the first groove 301 and the second groove 302 may be used as alignment marks for alignment between the circuit board 300 and the display panel 100. For example, since the display panel 100 and the circuit board 300 are attached to each other by the first conductive adhesive member 701, prior to such an attachment process, the first groove 301 and the second groove 302 may be used as alignment marks for alignment between the display panel 100 and the circuit board 300. When the first groove 301 and the second groove 302 are aligned, the aligned first and second grooves 301 and 302 may have a U-shape when viewed in a plan view shown in FIG. 4.

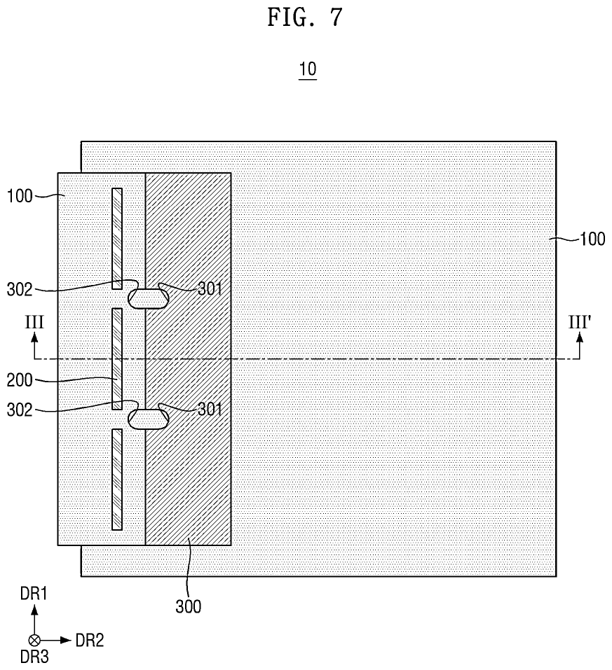

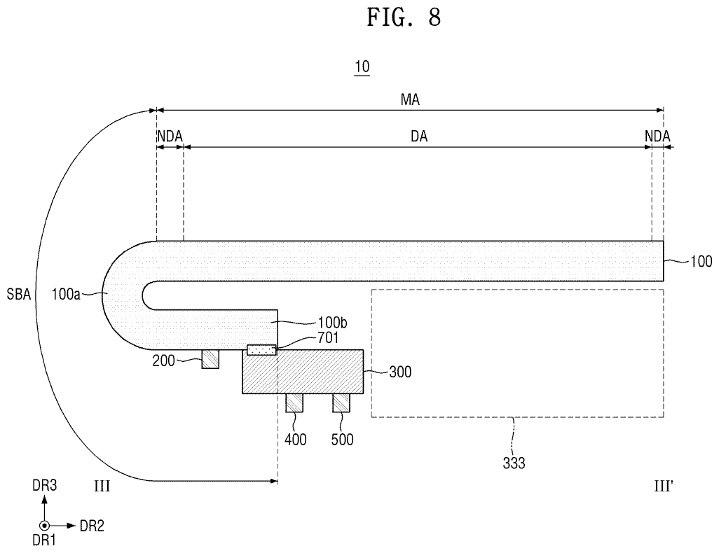

FIG. 7 is a plan view illustrating a display device according to still another embodiment, and FIG. 8 is a cross-sectional view taken along line III-III′ of FIG. 7.

Since the display device 10 of FIGS. 7 and 8 has a difference from the display device 10 of FIGS. 4 to 6 in the position of the circuit board 300, the following description will be based on the difference.

As shown in FIGS. 7 and 8, the circuit board 300 may overlap the sub-area SBA of the display panel 100 in a plan view. For example, the circuit board 300 may overlap the packaging area 100b of the sub-area SBA in the third direction DR3. In one embodiment, a portion (hereinafter, overlap portion) of the circuit board 300, which overlaps the sub-area SBA, may have an area smaller than a portion (hereinafter, a non-overlap portion) that does not overlap the sub-area SBA. In other words, an area of the overlap portion may be smaller than an area of the non-overlap portion.

In one embodiment, as shown in FIG. 7, the circuit board 300 may define at least one first groove 301 therein. The first groove 301 may have, for example, a concave shape recessed in the second direction DR2. The first groove 301 may improve rigidity of the circuit board 300.

In one embodiment, as shown in FIG. 7, the display panel 100 may define at least one second groove 302 therein. For example, the display panel 100 may define at least one second groove 302 in the packaging area 100b therein. The second groove 302 may have, for example, a concave shape recessed in the second reverse direction. In other words, the second groove 302 and the first groove 301 may have concave shapes recessed in directions opposite to each other. The second groove 302 may improve rigidity of the display panel 100.

According to the display device 10 of one embodiment shown in FIGS. 7 and 8, when the circuit board 300 and the display panel 100 are attached to each other, the first groove 301 and the second groove 302 may be used as alignment marks for alignment between the circuit board 300 and the display panel 100. For example, since the display panel 100 and the circuit board 300 are attached to each other by the first conductive adhesive member 701, prior to such an attachment process, the first groove 301 and the second groove 302 may be used as alignment marks for alignment between the display panel 100 and the circuit board 300. When the first groove 301 and the second groove 302 are aligned, in a plan view shown in FIG. 7, the aligned first and second grooves 301 and 302 may have an oval shape.

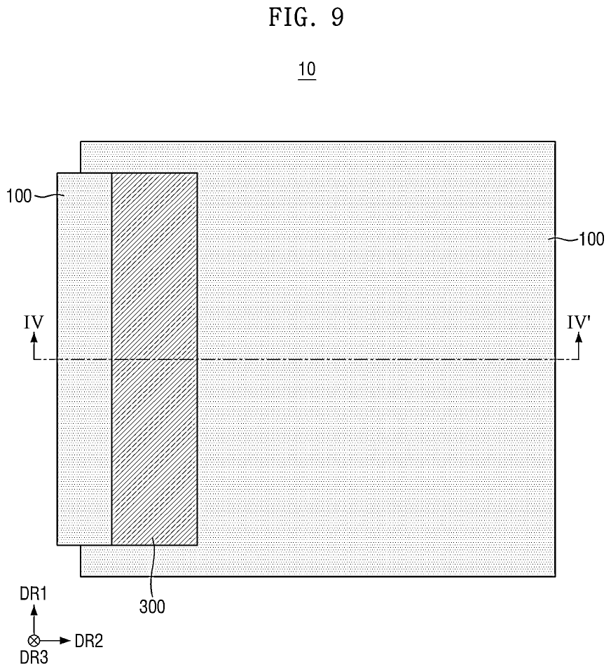

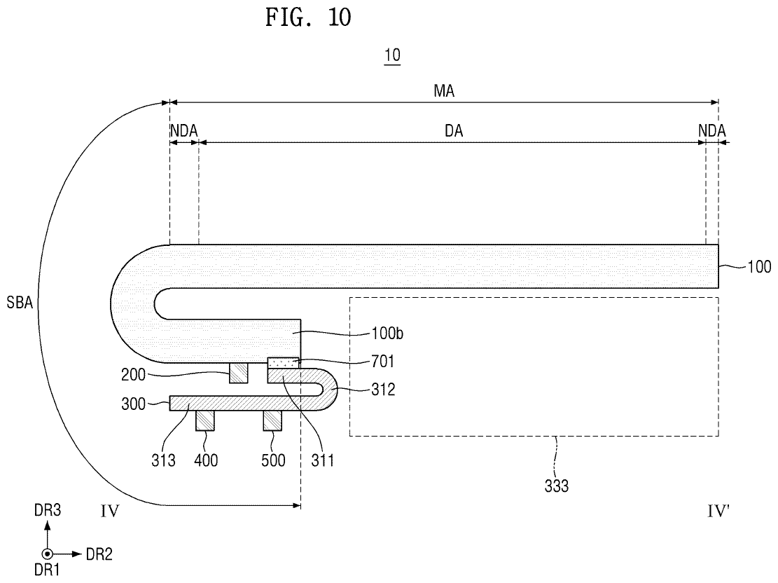

FIG. 9 is a plan view illustrating a display device according to yet another embodiment, and FIG. 10 is a cross-sectional view taken along line IV-IV′ of FIG. 9.

Since the display device 10 of FIGS. 9 and 10 has a difference from the display device 10 of FIGS. 7 and 8 in the position of the circuit board 300, the following description will be based on the difference.

As shown in FIGS. 9 and 10, the circuit board 300 may be attached to the packaging area 100b of the display panel 100 (e.g., the outer side OS of the packaging area 100b) through the first conductive adhesive member 701.

The circuit board 300 may include a connection area 311, a bending area 312 and a packaging area 313.

The connection area 311 of the circuit board 300 may be disposed on the sub-area SBA of the display panel 100. The connection area 311 of the circuit board 300 may be connected to the sub-area SBA of the display panel 100 through the first conductive adhesive member 701. For example, the connection area 311 of the circuit board 300 may be physically and electrically connected to the packaging area 100b of the sub-area SBA (e.g., the outer side OS of the packaging area 100b) through the first conductive adhesive member 701. The connection area 311 of the circuit board 300 may overlap the packaging area 100b of the display panel 100 in the third direction DR3.

The bending area 312 of the circuit board 300 may be disposed between the connection area 311 and the packaging area 313. One side of the bending area 312 may be in contact with the connection area 311, and the other side of the bending area 100a may be in contact with the packaging area 313. The bending area 312 may have a U-shape (or U-shaped cross-section) convexly protruded in the second direction DR2. The connection area 311 and the packaging area 313 may be connected to each other by the bending area 312. In one embodiment, the bending area 312 of the circuit board 300 may not overlap the packaging area 100b of the display panel 100 in a plan view. In one embodiment, the bending area 100a of the display panel 100 and the bending area 312 of the circuit board 300 may be protruded convexly in directions opposite to each other.

The above-described touch driver 400 and power supply unit 500 may be disposed on the packaging area 313 of the circuit board 300. For example, the above-described touch driver 400 and power supply unit 500 may be packaged on the packaging area 313 of the circuit board 300.

The packaging area 313 of the circuit board 300 may overlap the sub-area SBA of the display panel 100 in the third direction DR3. For example, the packaging area 313 of the circuit board 300 may overlap the packaging area 100b of the sub-area SBA in the third direction DR3. In addition, the packaging area 313 of the circuit board 300 may overlap the display driver 200 in the third direction DR3. The display driver 200 may be disposed between the packaging area 313 of the circuit board 300 and the packaging area 100b of the display panel 100.

According to the display device 10 of one embodiment shown in FIGS. 9 and 10, a portion (hereinafter, overlap portion) of the circuit board 300, which overlaps the sub-area SBA of the display panel 100, may have an area larger than an area of a portion (hereinafter, non-overlap portion) that does not overlap the sub-area SBA of the display panel 100. In other words, an area of the overlap portion may be larger than an area of the non-overlap portion. As the circuit board 300 is disposed to be closer to the sub-area SBA as described above, the area of the set area 333 may be increased.

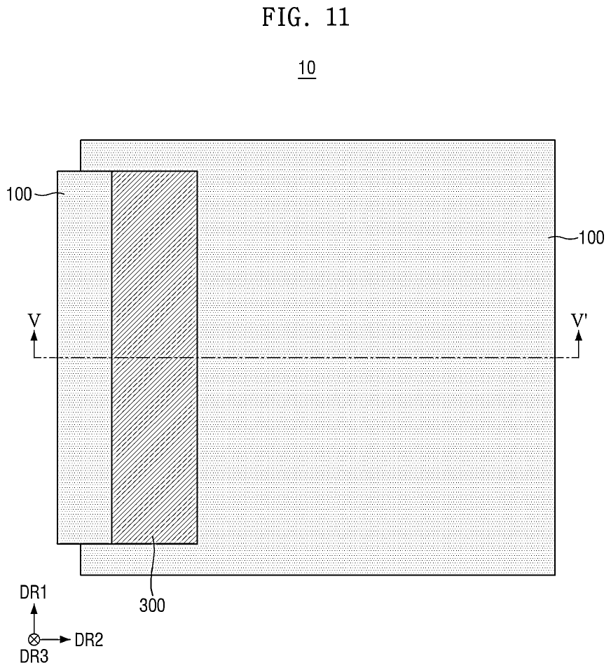

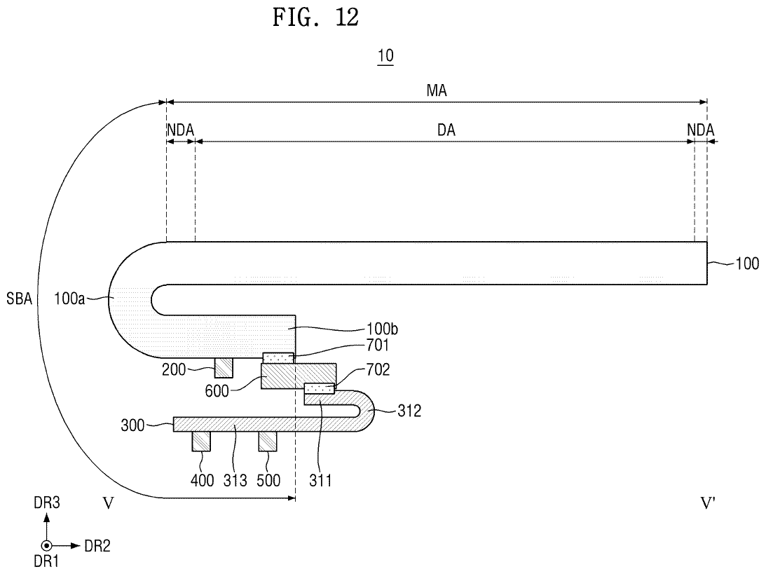

FIG. 11 is a plan view illustrating a display device according to another embodiment, and FIG. 12 is a cross-sectional view taken along line V-V′ of FIG. 10.

Since the display device 10 of FIGS. 11 and 12 has a difference from the display device 10 of FIGS. 9 and 10 in that it further includes the intermediate board 600, the following description will be based on the difference.

As shown in FIGS. 11 and 12, the intermediate board 600 may be physically and electrically connected to the packaging area 100b of the display panel 100 and the connection area 311 of the circuit board 300. For example, one side of the intermediate board 600 may be attached to the packaging area 100b of the display panel 100 (e.g., the outer side OS of the packaging area 100b) through the first conductive adhesive member 701, and the other side of the intermediate board 600 may be attached to the connection area 311 of the circuit board 300 through the second conductive adhesive member 702.

The circuit board 300 of FIGS. 11 and 12 may be the same as the circuit board 300 of FIGS. 9 and 10 described above.

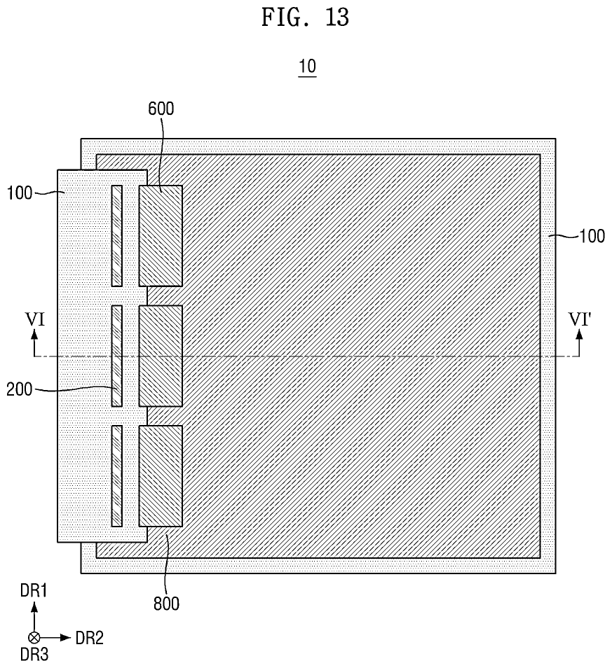

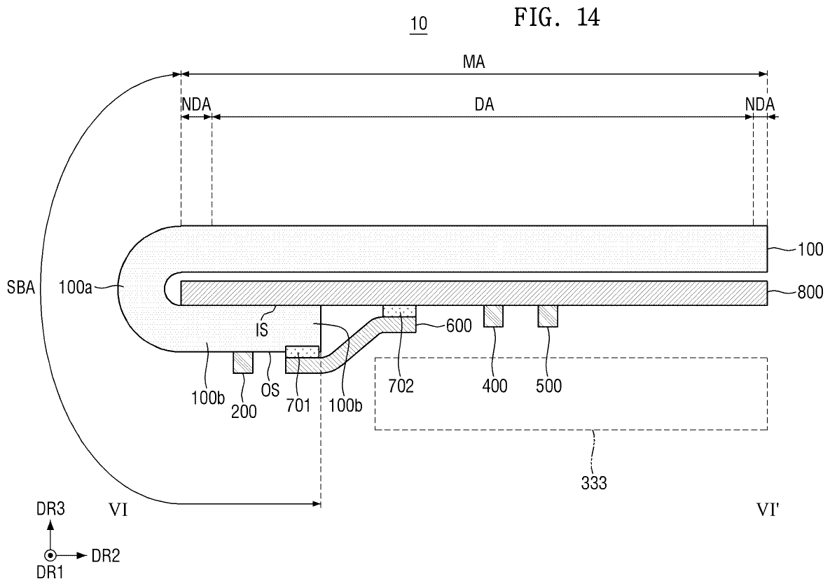

FIG. 13 is a plan view illustrating a display device according to still another embodiment, and FIG. 14 is a cross-sectional view taken along line VI-VI′ of FIG. 13.

Since the display device 10 of FIGS. 13 and 14 has a difference from the display device 10 of FIGS. 1 to 3 in that it further includes a reinforcing member 800, the following description will be based on the difference.

The reinforcing member 800 may perform a buffering function for external impact, an antistatic function and a light blocking function. To this end, according to one embodiment, the reinforcing member 800 may be disposed between the main area MA and the packaging area 100b of the display panel 100. In this case, one end of the reinforcing member 800 may face the bending area 100a of the display panel 100. In addition, for example, the touch driver 400 and the power supply unit 500 may be disposed on the reinforcing member 800. In other words, the touch driver 400 and the power supply unit 500 may be packaged on the reinforcing member 800. To this end, in one embodiment, the reinforcing member 800 may be a flexible printed circuit board (FPCB), a printed circuit board (PCB), or a flexible film such as a chip on film (COF). In addition, in one embodiment, the reinforcing member 800 may be, for example, a rigid printed circuit board. In one embodiment, the reinforcing member 800 may overlap the display driver 200 in the third direction DR3.

The intermediate board 600 may be physically and electrically connected to the packaging area 100b of the display panel 100 (e.g., the outer side OS of the packaging area 100b) through the first conductive adhesive member 701. In addition, the intermediate board 600 may be physically and electrically connected to the reinforcing member 800 through the second conductive adhesive member 702. Therefore, the reinforcing member 800 may be electrically connected to the display panel 100 through the intermediate board 600.

According to the display device 10 of one embodiment shown in FIGS. 13 and 14, since the reinforcing member 800 may perform a function of the circuit board 300 as well as the buffering function, the circuit board 300 may be omitted. Therefore, the manufacturing cost of the display device 10 may be reduced. In addition, since the intermediate board 600 and the reinforcing member 800 are electrically connected to each other, it is advantageous for ground conduction between the intermediate board 600 and the reinforcing member 800.

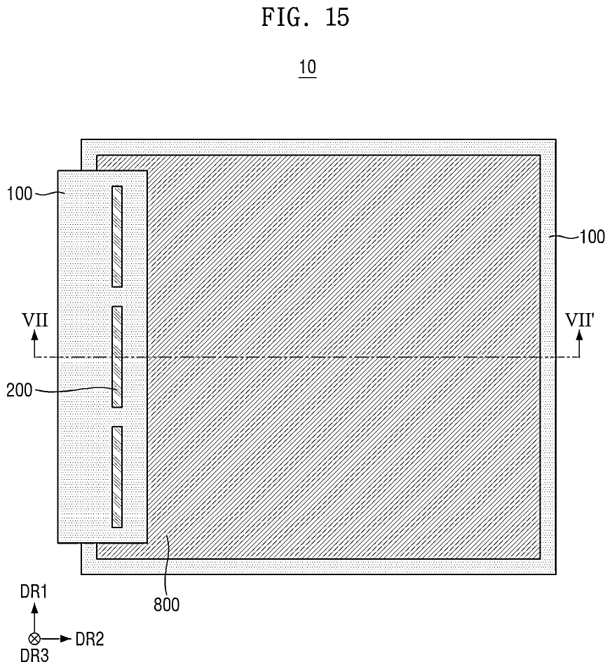

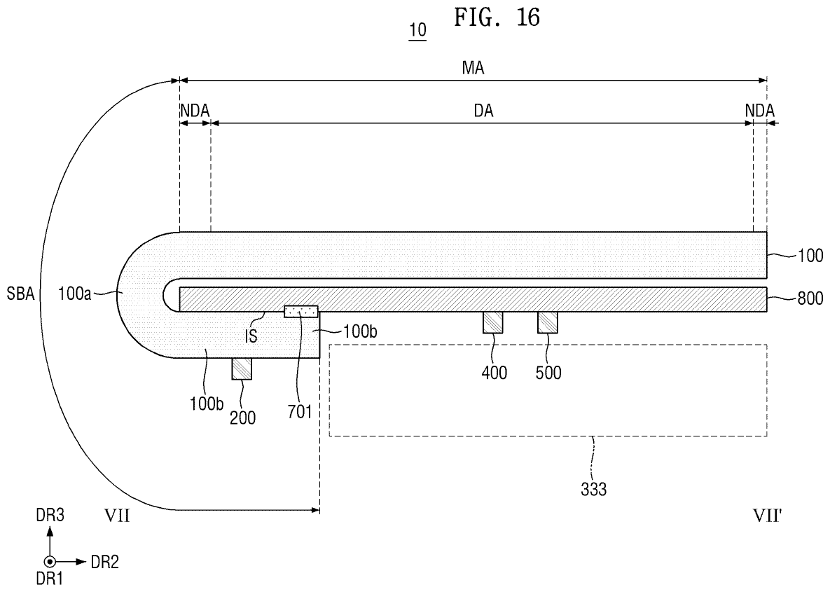

FIG. 15 is a plan view illustrating a display device according to yet another embodiment, and FIG. 16 is a cross-sectional view taken along line VII-VII′ of FIG. 15.

Since the display device 10 of FIGS. 15 and 16 has a difference from the display device 10 of FIGS. 13 and 14 in that the reinforcing member 800 is directly connected to the display panel 100, the following description will be based on the difference.

As shown in FIGS. 15 and 16, the reinforcing member 800 may be physically and electrically connected to the packaging area 100b of the display panel 100 (e.g., the inner side IS of the packaging area 100b) through the first conductive adhesive member 701.

The reinforcing member 800 of FIGS. 15 and 16 may be the same as the reinforcing member 800 of FIGS. 13 and 14 described above.

According to the display device 10 of the embodiment shown in FIGS. 15 and 16, since the reinforcing member 800 may perform the function of the circuit board 300 as well as the buffering function, the circuit board 300 may be omitted. In addition, since the reinforcing member 800 is directly connected to the display panel 100, the intermediate board 600 may be omitted. Therefore, the manufacturing cost of the display device 10 may be reduced.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a display panel including a main area and a sub-area, wherein the sub-area is bent and extended from the main area;
a reinforcing member disposed between the main area and the sub-area of the display panel and connected to the display panel; and
a first circuit component disposed on the reinforcing member.

2. The display device of claim 1, wherein the reinforcing member is directly connected to the sub-area of the display panel.

3. The display device of claim 2, wherein the reinforcing member is directly connected to an inner side of the sub-area of the display panel.

4. The display device of claim 2, wherein the sub-area of the display panel includes:
a bending area extended from the main area and bent; and
a packaging area extended from the bending area and on which a second circuit component is disposed.

5. The display device of claim 4, wherein the reinforcing member is directly connected to the packaging area of the display panel.

6. The display device of claim 5, wherein the reinforcing member is directly connected to an inner side of the packaging area of the display panel.

7. The display device of claim 6, further comprising a conductive adhesive member physically and electrically connecting the reinforcing member to the packaging area of the display panel.

8. The display device of claim 1, further comprising a second circuit component disposed in the sub-area of the display panel.

9. The display device of claim 1, further comprising an intermediate board connecting the reinforcing member with the display panel.

10. The display device of claim 9, wherein a first side of the intermediate board is connected to the sub-area of the display panel, and
a second side of the intermediate board is connected to the reinforcing member.

11. The display device of claim 10, wherein the sub-area of the display panel includes
a bending area extended from the main area and bent; and
a packaging area extended from the bending area and connected to the intermediate board, and on which a second circuit component is disposed.

12. The display device of claim 11, wherein the first side of the intermediate board is connected to the packaging area of the display panel.

13. The display device of claim 12, wherein the first side of the intermediate board is connected to an outer side of the packaging area of the display panel.

14. The display device of claim 13, further comprising:
a first conductive adhesive member physically and electrically connecting the first side of the intermediate board with the packaging area of the display panel; and
a second conductive adhesive member physically and electrically connecting the second side of the intermediate board with the reinforcing member.

15. The display device of claim 1, wherein one end of the reinforcing member faces a bending area of the display panel.

16. The display device of claim 1, wherein the reinforcing member includes one of a flexible printed circuit board, a printed circuit board, a chip on film and a rigid printed circuit board.

17. The display device of claim 1, wherein the first circuit component on the reinforcing member includes a touch driver and a power supply unit.

18. The display device of claim 1, further comprising a display driver disposed on the display panel.

19. The display device of claim 18, wherein the display driver is disposed on the sub-area of the display panel.

20. The display device of claim 19, wherein the reinforcing member overlaps the display driver in a plan view.
